(19) United States
(12) Patent Application Publication
(10) Pub. No.: US 2017/0092562 A1
(43) Pub. Date: Mar. 30, 2017

(54) HEAT DISSIPATION STRUCTURE FOR SEMICONDUCTOR CIRCUIT BREAKER

(71) Applicant: YAZAKI CORPORATION, Tokyo (JP)

(72) Inventor: Hiroteru Kato, Shizuoka (JP)

(21) Appl. No.: 15/374,643

(22) Filed: Dec. 9, 2016

Related U.S. Application Data
(63) Continuation of application No. PCT/JP2015/064022, filed on May 15, 2015.

(30) Foreign Application Priority Data
Jul. 9, 2014 (JP) 2014-141498

(51) Int. Cl. H01L 23/427; H01R 25/16; H01L 23/31; H01L 23/367

(52) U.S. Cl. CPC H01L 23/427; H01L 23/367; H01R 25/165; H01L 23/3107

(57) ABSTRACT

A heat dissipation structure for a semiconductor circuit breaker to release heat generated by the semiconductor circuit breaker which is capable of switching between conduction and blocking between predetermined targets, the heat dissipation structure compring a bus bar which is a plate material made of metal on which the semiconductor circuit breaker is provided, and a heat pipe which is a thin sheet long member made of metal. The semiconductor circuit breaker is mounted on a surface of the busbar. The heat pipe is disposed so that one part of the heat pipe contacts an opposite surface from the surface of the bus bar and another part of the heat pipe is connected to a heat dissipation member.

### CROSS REFERENCE TO RELATED APPLICATIONS

This application is a continuation of PCT application No. PCT/JP2015/064022, which was filed on May 15, 2015 based on Japanese Patent Application (No. 2014-141498) filed on Jul. 9, 2014, the contents of which are incorporated herein by reference.

### BACKGROUND OF THE INVENTION

Field of the Invention

The present invention relates to a heat dissipation structure for a semiconductor circuit breaker.

Description of Related Art

In the related art, a semiconductor device is suggested that is provided with a power element, a control element that controls the power element, a wiring board on which the elements are mounted, and a heat sink for heating that is formed from an iron-based metal (for example, refer to Patent Literature 1: JP-A-2005-328015). The heat capacity is raised in the semiconductor device by forming the heat sink using the iron-based metal and heat that is generated by the power element is efficiently stored in the heat sink. Thereby, the semiconductor element controls heat transfer to the control element and influence imparted to the control element by the heat that is generated by the power element is small. Furthermore, linear expansion of a resin is suppressed and peeling of the members and the resin is prevented by sealing (so-called mold forming) the members using the resin that has a higher glass-transition point than a maximum temperature at which the power element is able to operate.

Furthermore, a power control device is suggested in which a packaged semiconductor element is installed on a heat sink, and miniaturization, high output, and high service life of the semiconductor element are possible by causing the release of heat from the semiconductor element from the heat sink and a housing that contacts the heat sink (for example, refer to Patent Literature 2: JP-A-2012-200141). The power control device increases thermal emissivity by subjecting a front surface of the heat sink to alumite treatment and improves heat dissipation using the heat sink.

Furthermore, an electric junction box is suggested in which heat dissipation is increased by installing a resin sealed semiconductor element and a heat dissipation plate within a case and exposing the whole surface of the heat dissipation plate to the outside of the case (for example, refer to Patent Literature 3: JP-A-2003-224919). The electric junction box is prevented from increasing in size by the end portions of each bus bar that is connected by the semiconductor element being folded back to the heat dissipation plate side.
[Patent Literature 1] JP-A-2005-328015
[Patent Literature 2] JP-A-2012-200141
[Patent Literature 3] JP-A-2003-224919

Any device in a related arts aims at reducing the size of the entirety of the device by using the semiconductor element, not mechanical relay. Meanwhile, the devices in the related arts adopt the heat dissipation structure described above since a heating value increases during operation of the semiconductor element.

However, in the heat dissipation structure that is adopted by the devices in the related arts, since a plate shape heat sink (heat dissipation plate) is used, the amount of heat dissipation may be insufficient according to the operation state of the semiconductor element. Therefore, as a countermeasure to when a heat generation amount of the semiconductor element is increased, a new heat dissipation structure (for example, a fin shape heat sink and a large area heat sink) may be necessary.

In this manner, although the devices in the related arts aim at reducing the size of the device using the semiconductor element, it may be desirable to increase the size of the heat dissipation structure to correspond to heat generation of the semiconductor element. That is, the devices in the related arts may not be sufficient in both heat dissipation and reduction of size.

The present invention is carried out in order to solve the problem of the related art, and an object of the present invention is to provide a heat dissipation structure for a semiconductor circuit breaker that is able to achieve both heat dissipation and reduction of size.

### SUMMARY

In order to realize the object described above, the heat dissipation structure for a semiconductor circuit breaker according to the present invention has the characteristics of (1) to (4) described below.
(1) A heat dissipation structure for a semiconductor circuit breaker to release heat generated by the semiconductor circuit breaker which is capable of switching between conduction and blocking between predetermined targets, the heat dissipation structure compring:

a bus bar which is a plate material made of metal on which the semiconductor circuit breaker is provided; and

a heat pipe which is a thin sheet long member made of metal,

wherein the semiconductor circuit breaker is mounted on a surface of the busbar, and

wherein the heat pipe is disposed so that one part of the heat pipe contacts an opposite surface from the surface of the bus bar and another part of the heat pipe is connected to a heat dissipation member.
(2) The heat dissipation structure according to the above mentioned (1), further comprising:

a second bus bar made of metal which is provided on an opposite side from the bus bar to interpose the semiconductor circuit breaker.
(3) The heat dissipation structure according to the above mentioned (2), further comprising:

a control terminal which transmits a control signal to control the switching by the semiconductor circuit breaker to the semiconductor circuit breaker; and

a resin member which seals an entirety of the semiconductor circuit breakers and apart of each of the control terminal, the bus bar, and the second bus bar,

wherein a remainder of the control terminal, a remainder of the second bus bar, and a portion of a remainder of the bus bar, which are not sealed by the resin member, protrude in the same direction from the resin member, and

wherein another portion of the remainder of the bus bar which is not sealed by resin member, contacts the heat pipe.
(4) The heat dissipation structure according to the above mentioned (1),

wherein when the semiconductor circuit breaker is provided in a vicinity of a battery which is mounted in a vehicle, at least one of a vehicle body of the vehicle and a cover of the battery is used as the heat dissipation member.

According to the heat dissipation structure for a semiconductor circuit breaker with the configuration of (1) described above, a bus bar made of metal that is provided with the semiconductor circuit breaker, and a heat dissipation member are connected via a heat pipe made of metal. Therefore, for example, in a case where the semiconductor circuit breaker is provided in the vicinity of a battery mounted in a vehicle, it is not necessary to provide the heat dissipation member itself by setting the heat dissipation member to another member of a battery pack cover, a vehicle body, and the like. Moreover, if the heat pipe is connected to a large metal material (heat dissipation member), it is possible to sufficiently release heat even if the heat generation amount of the semiconductor circuit breaker is great. Consequently, it is possible to achieve both heat dissipation and reduction of size.

According to the heat dissipation structure for a semiconductor circuit breaker with the configuration of (2) described above, since a second bus bar made of metal that is provided on the opposite side from the bus bar that interposes the semiconductor circuit breaker is provided, it is possible to perform heat dissipation through the second bus bar in addition to heat dissipation through the heat pipe and it is possible to further increase heat dissipation.

According to the heat dissipation structure for a semiconductor circuit breaker with the configuration of (3) described above, since a part (remainder) on which resin sealing of a control terminal, the second bus bar, and the bus bar is not carried out protrudes in the same direction from the resin member, it is possible to configure the semiconductor circuit breaker as a connector in which the control terminal, the second bus bar, and the bus bar are intensively disposed in the same direction. Furthermore, since another portion of the part (remainder) on which resin sealing of the bus bar is not carried out contacts the heat pipe, resin sealing does not influence heat transmission due to the heat pipe.

According to the heat dissipation structure for a semiconductor circuit breaker with the configuration of (4) described above, it is possible to sufficiently secure heat dissipation.

According to the present invention, it is possible to provide a heat dissipation structure for a semiconductor circuit breaker that is able to achieve both heat dissipation and reduction of size.

The present invention is described simply above. Furthermore, the details of the present invention are further defined with the aspects for carrying out the invention (hereinafter referred to as “embodiments”) which will be described below, with reference to the attached drawings.

### BRIEF DESCRIPTION OF THE DRAWINGS

FIG. 1 is a perspective view illustrating a heat dissipation structure for a semiconductor circuit breaker according to an embodiment of the present invention.

FIG. 2 is a sectional view taken along line A-A of the heat dissipation structure indicated in FIG. 1.

FIG. 3 is a sectional view taken along line B-B of the heat dissipation structure indicated in FIG. 1.

FIG. 4 is a perspective view illustrating a heat dissipation structure for a semiconductor circuit breaker that is a connector.

FIG. 5 is a perspective view of the heat dissipation structure indicated in FIG. 4 viewed from the opposite side.

FIG. 6 is a perspective view illustrating a state in which the connector indicated in FIGS. 4 and 5 is connected to a monitoring unit that monitors a state of a fuel cell.

### DETAILED DESCRIPTION

Appropriate embodiments will be described below with reference to the drawings, but the present invention is not limited to the following embodiments.

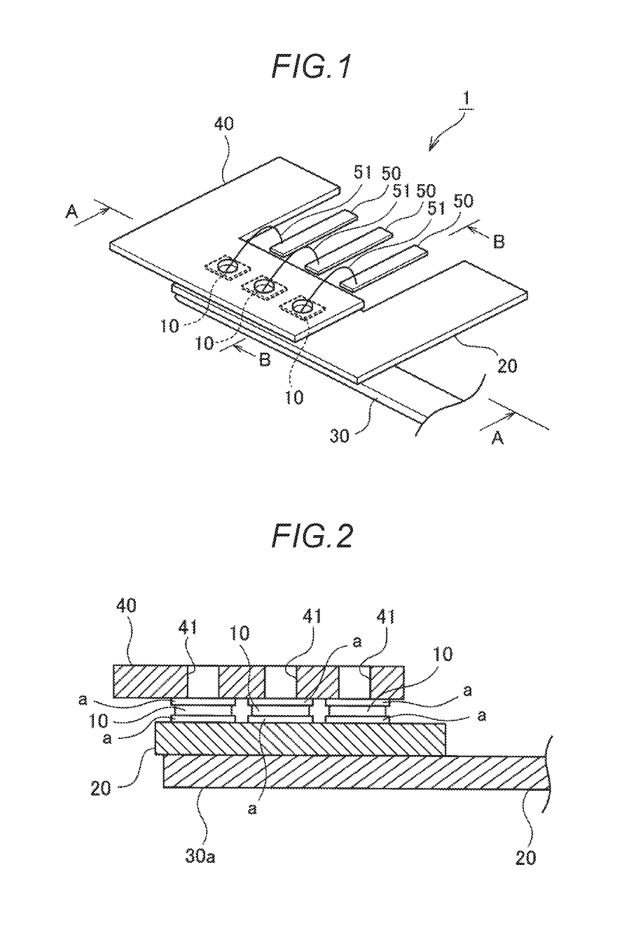

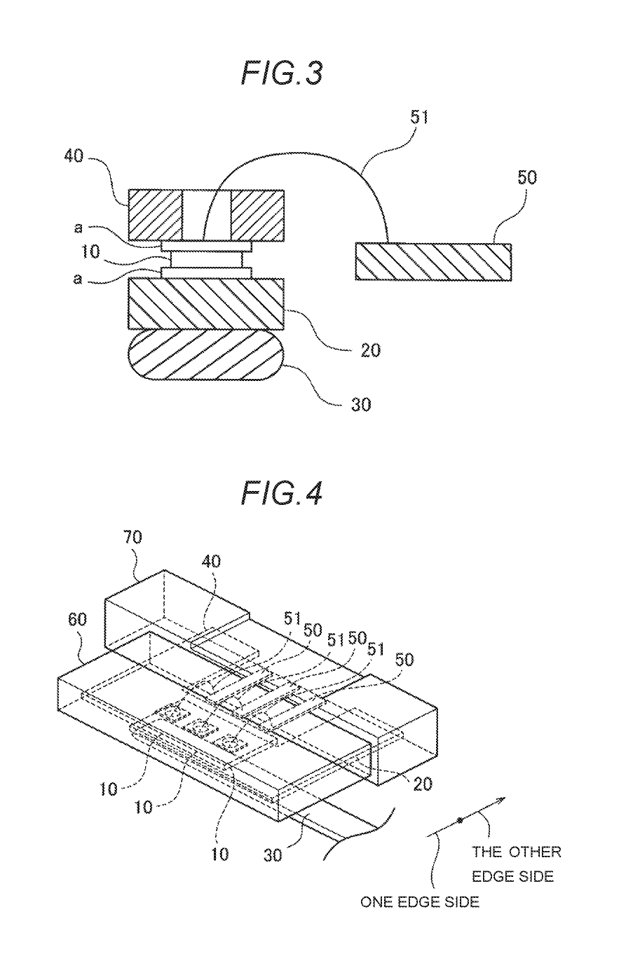

FIG. 1 is a perspective view illustrating a heat dissipation structure for a semiconductor circuit breaker according to an embodiment of the present invention. FIG. 2 is a sectional view taken along line A-A of the heat dissipation structure indicated in FIG. 1, and FIG. 3 is a sectional view taken along line B-B of the heat dissipation structure indicated in FIG. 1.

A heat dissipation structure 1 for a semiconductor circuit breaker according to the present embodiment as indicated in FIGS. 1 to 3 is a structure for efficiently discharging heat that is generated by a plurality of semiconductor circuit breakers 10. The respective semiconductor circuit breakers 10 are configured by a semiconductor chip that is able to switch between conduction and blocking between predetermined targets. For example, the semiconductor circuit breaker 10 is a power device.

Such a heat dissipation structure 1 is provided with a bus bar 20 and a heat pipe 30. The bus bar 20 is a plate material made of metal on which a plurality of semiconductor circuit breakers 10 are mounted. The plurality of semiconductor circuit breakers 10 are mounted on one surface of the bus bar 20 via a die-bonding material a. For example, the bus bar 20 is configured by metal such as copper, and in the present embodiment, as shown in FIG. 1, is configured by an L shaped flat plate in planar view.

The heat pipe 30 is a thin sheet long member made of metal that contacts the bus bar 20. The heat pipe 30 is provided to contact a surface on the opposite side from a surface on which the plurality of semiconductor circuit breakers 10 of the bus bar 20 are mounted. In addition, although illustration is omitted, an end portion side of the heat pipe 30 is connected to a heat dissipation member on the opposite side from an end portion 30a on a side that contacts the bus bar 20. That is, the heat pipe 30 is disposed such that one part contacts the bus bar 20 and another part is connected to the heat dissipation member.

Here, the heat dissipation member is various members with a high degree of heat dissipation, and in a case where, for example, the heat dissipation structure 1 according to the present embodiment is used in a cell-related technology, a cover of the battery pack and the like is adopted in the heat dissipation member, and in a case where the heat dissipation structure 1 according to the present embodiment is used in a vehicle-related technology, a vehicle body and the like is adopted in the heat dissipation member.

Furthermore, as shown in FIGS. 1 to 3, the heat dissipation structure 1 is provided with a second bus bar 40 and a plurality of gate bus bars (control terminals) 50. The second bus bar 40 is a plate material made of metal that is provided on the opposite surface of the bus bar 20 interposing the semiconductor circuit breaker 10, and is mounted on the plurality of semiconductor circuit breakers 10 via the die-bonding material a. In the same manner as the bus bar 20, for example, the second bus bar 40 is configured by metal such as copper, and in the present embodiment, as shown in FIG. 1, is configured by an L shaped flat plate in planar view.

In addition, as apparent from FIG. 1, the bus bar 20 and the second bus bar 40 are disposed in the L shape facing each other left and right, and are disposed to interpose the semiconductor circuit breaker 10.

The plurality of gate bus bars 50 are control terminals for respectively transmitting a control signal for controling switching (on and off) between conduction and blocking according to the plurality of semiconductor circuit breakers 10 to the plurality of semiconductor circuit breakers 10. Each of the plurality of gate bus bars 50 is connected to each semiconductor circuit breaker 10 using a bonding wire 51 via an opening 41 that is formed on the second bus bar 40.

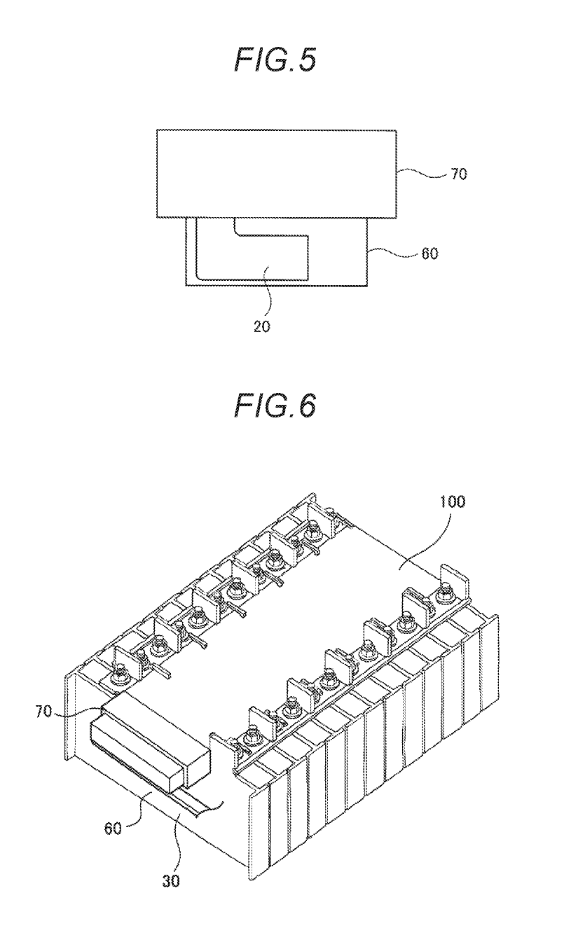

Here, it is desirable to use each portion configuration integrally as the connector using resin and the like. FIG. 4 is a perspective view illustrating the heat dissipation structure 1 for the resin sealed semiconductor circuit breaker 10 viewed from an upper surface, and FIG. 5 is a perspective view of the heat dissipation structure 1 indicated in FIG. 4 viewed from the lower surface side. Note that, for convenience of description, FIG. 4 is an illustration in a state in which an internal configuration is the perspective. In addition, FIG. 5 is an illustration omitting the heat pipe 30 from a viewpoint of ease of viewing of the drawing.

As shown in FIGS. 4 and 5, the entirety of the plurality of semiconductor circuit breakers 10 and a part of the respective plurality of gate bus bars 50, the bus bar 20, and the second bus bar 40 are sealed using a resin member 60.

Described in detail, in the plurality of gate bus bars 50, the side (one end side in the drawing) on which the semiconductor circuit breakers 10 are provided is sealed using the resin member 60, and a part that is not sealed with resin (remainder, the other end side in the drawing) protrudes outside of the resin member 60. In other words, the remainder of the gate bus bar 50 is opened outside of the resin member 60 (in an open state). Also in the second bus bar 40, one end side is sealed using the resin member 60, and the other end side that is the remainder protrudes in the same direction as the remainder of the gate bus bar 50.

In the same manner as the second bus bar 40, in the bus bar 20, one end side is sealed by the resin member 60, and the other end side that is the remainder protrudes in the same direction as the remainder of the gate bus bar 50. As shown in FIG. 5, the other portion of the remainder of the bus bar 20 is exposed outside the resin member 60 to contact the heat pipe 30.

As described above, since the plurality of gate bus bars 50, the bus bar 20, and the second bus bar 40 protrude in the same direction from the resin member 60, it is possible to use the semiconductor circuit breaker 10 as the connector that is centrally disposed at the same side. Note that, as shown in FIGS. 4 and 5, a hood portion 70 that covers the periphery of the gate bus bars 50, the bus bar 20, and the second bus bar 40 are integrally formed with the resin member 60 on the other end side of the gate bus bars 50, the bus bar 20, and the second bus bar 40, and the hood portion 70 plays a role of protecting the other end side of the gate bus bars 50, the bus bar 20, and the second bus bar 40.

Furthermore, the bus bar 20 is open at a contact position of the heat pipe 30 such that heat dissipation is not lowered during sealing with resin as described above, and sealing with resin does not influence heat transmission using the heat pipe 30.

FIG. 6 is a perspective view illustrating a state in which the connector indicated in FIGS. 4 and 5 is connected to a monitoring unit that monitors a state of a secondary battery that is provided in a vehicle and the like. As shown in FIG. 6, a control portion for monitoring whether the secondary battery is in an abnormal state and the like is provided in a monitoring unit 100, and the connector that is indicated in FIGS. 4 and 5 is connected such that a signal from the control portion is input, for example, to a plurality of gate bus bars 50. Thereby, the heat dissipation structure 1 itself is able to be integrated with the monitoring unit 100.

Next, the actions of the heat dissipation structure 1 according to the present embodiment will be described. First, the semiconductor circuit breaker 10 generates heat. At this time, heat from the semiconductor circuit breaker 10 reaches the bus bar 20 and the second bus bar 40 through the die-bonding material a. In particular, heat that reaches the bus bar 20 reaches the heat pipe 30 and is transmitted up to the heat dissipation member through the heat pipe 30. Thereby, heat that is generated by the semiconductor circuit breaker 10 is appropriately released.

Thereby, according to the heat dissipation structure 1 of the semiconductor circuit breaker 10 according to the present embodiment, for example, it is not necessary to provide the heat dissipation member itself by setting the heat dissipation member to another member of a battery pack cover, a vehicle body, or the like. Moreover, the heat pipe 30 is connected to a large metal material (heat dissipation member), thereby it is possible to sufficiently secure heat dissipation using the heat dissipation member through the heat pipe 30 and it is possible to achieve both heat dissipation and reduction of size even if the heat generation amount of the semiconductor circuit breaker 10 is great.

In addition, since the second bus bar 40 made of metal is provided in the heat dissipation structure 1, it is possible to perform heat dissipation through the second bus bar 40 in addition to heat dissipation from the bus bar 20 through the heat pipe 30 and it is possible to further increase heat dissipation.

In addition, since the part (remainder) on which sealing with resin of the gate bus bars 50, the second bus bar 40, and the bus bar 20 is not carried out protrudes in the same direction from the resin member 60, it is possible to use the semiconductor circuit breaker 10 as the connector that is centrally disposed in the same direction. Furthermore, in the other portion of the part (remainder) on which resin sealing of the second bus bar 20 is not carried out, resin sealing may not influence heat transmission due to the heat pipe 30 by contacting the heat pipe 30.

Furthermore, the heat dissipation structure 1 of the semiconductor circuit breaker 10 according to the present embodiment has the following advantages in a case of a comparison to the heat dissipation structure in Patent Literature 1. First, since the heat dissipation structure in Patent Literature 1 increases the heat capacity of a heat sink material configuring the heat sink material of iron, there is problem from the viewpoint of performing instantaneous heat dissipation. Meanwhile, in the heat dissipation structure 1 according to the present embodiment, since a thin plate form heat pipe 30 is used, such a problem is not generated. Furthermore, since the heat dissipation structure in Patent Literature 1 uses an alumina substrate, heat resistance is increased from a low of ceramic-specific thermal conductivity, but it is possible to substantially reduce heat resistance since it is not necessary to use ceramic in the heat dissipation structure 1 according to the present embodiment.

In addition, the heat dissipation structure 1 of the semiconductor circuit breaker 10 according to the present embodiment has the following advantages in a case of a comparison to the heat dissipation structure in Patent Literature 2. First, in the heat dissipation structure in Patent Literature 2, heat from the semiconductor element is released from the heat sink, and a housing that contacts the heat sink, and there is no heat dissipation efficiency for reducing a heat dissipation area. Meanwhile, in a point of heat dissipation efficiency for heat dissipation through the heat pipe 30, the heat dissipation structure 1 according to the present embodiment has a superior heat dissipation structure to Patent Literature 2. In addition, in the heat dissipation structure of Patent Literature 2, since the resin sealed semiconductor element is mounted in the heat sink, and furthermore, the outside is covered by the housing, the semiconductor element has a structure covering to overlap and heat resistance is great. Meanwhile, in the heat dissipation structure 1 according to the present embodiment, it is not necessary to adopt a cover structure for heat dissipation through the heat pipe 30. Additionally, in the heat dissipation structure of Patent Literature 2, there are many components for fixing the semiconductor element to the heat sink using a plate spring. Meanwhile, in the heat dissipation structure 1 according to the present embodiment, it is possible to suppress an increase in a number of components since the semiconductor circuit breaker 10 is connected to the heat pipe 30 and the like via the die-bonding material a.

Here, the characteristics of the embodiment of the heat dissipation structure for the semiconductor circuit breaker according to the present invention described above are listed and briefly summarized in (1) to (4) below.

(1) A heat dissipation structure for a semiconductor circuit breaker (10) to release heat generated by the semiconductor circuit breaker which is capable of switching between conduction and blocking between predetermined targets, the heat dissipation structure compring:

a bus bar (20) which is a plate material made of metal on which the semiconductor circuit breaker is provided; and

a heat pipe (30) which is a thin sheet long member made of metal,

wherein the semiconductor circuit breaker is mounted on a surface of the busbar, and

wherein the heat pipe is disposed so that one part of the heat pipe contacts an opposite surface from the surface of the bus bar and another part of the heat pipe is connected to a heat dissipation member.

(2) The heat dissipation structure according to (1), further comprising:

a second bus bar (40) made of metal which is provided on an opposite side from the bus bar (20) to interpose the semiconductor circuit breaker (10).

(3) The heat dissipation structure according to (2), further comprising:

a control terminal (gate bus bar 50) which transmits a control signal to control the switching by the semiconductor circuit breaker (10) to the semiconductor circuit breaker; and

a resin member (60) which seals an entirety of the semiconductor circuit breakers (10) and a part of each of the control terminal (50), the bus bar (20), and the second bus bar (40),

wherein a remainder of the control terminal, a remainder of the second bus bar, and a portion of a remainder of the bus bar, which are not sealed by the resin member, protrude in the same direction from the resin member, and

wherein another portion of the remainder of the bus bar which is not sealed by resin member, contacts the heat pipe.

(4) The heat dissipation structure according to (1),

wherein when the semiconductor circuit breaker (10) is provided in a vicinity of a battery which is mounted in a vehicle, at least one of a vehicle body of the vehicle and a cover of the battery is used as the heat dissipation member.

The present invention is described in detail or with reference to a specific embodiment, but it is obvious to a person skilled in the art that it is possible to make various changes and modifications without departing from the spirit and scope of the present invention.

For example, it is assumed that the heat dissipation structure 1 for the semiconductor circuit breaker 10 according to the present embodiment is used for a vehicle, but is not limited thereto, and may be used in a stationary type. Furthermore, use is possible even in a low voltage source.

Furthermore, the semiconductor circuit breaker 10 in the present embodiment is assumed to be a power semiconductor element that utilizes gallium nitride or silicon carbide, but is not particularly limited thereto.

Additionally, it is desirable the heat dissipation structure 1 according to the present embodiment is integrated by sealing with resin, but it is not necessary to seal with resin. Furthermore, the second bus bar 40 may not be provided according to the use.

Furthermore, the heat dissipation structure 1 according to the present embodiment performs heat dissipation with respect to three semiconductor circuit breakers 10, but is not limited to three, and may perform heat dissipation with respect to the one, two, or four or more semiconductor circuit breakers 10.

### INDUSTRIAL APPLICABILITY

According to the present invention, it is possible to achieve both heat dissipation and reduction of size of the semiconductor circuit breaker. The present invention that accomplishes the effect has a use that relates to a heat dissipation structure for a semiconductor circuit breaker.

### DESCRIPTION OF REFERENCE NUMERALS AND SIGNS

1 HEAT DISSIPATION STRUCTURE

10 SEMICONDUCTOR CIRCUIT BREAKER

20 BUS BAR

30 HEAT PIPE

30a END PORTION

40 SECOND BUS BAR

41 OPENING

50 GATE BUS BAR (CONTROL TERMINAL)

51 BONDING WIRE

60 RESIN MEMBER

70 HOOD PORTION

100 MONITORING UNIT

a DIE-BONDING MATERIAL

What is claimed is:

1. A heat dissipation structure for a semiconductor circuit breaker to release heat generated by the semiconductor circuit breaker which is capable of switching between conduction and blocking between predetermined targets, the heat dissipation structure compring:
a bus bar which is a plate material made of metal on which the semiconductor circuit breaker is provided; and
a heat pipe which is a thin sheet long member made of metal,
wherein the semiconductor circuit breaker is mounted on a surface of the busbar, and
wherein the heat pipe is disposed so that one part of the heat pipe contacts an opposite surface from the surface of the bus bar and another part of the heat pipe is connected to a heat dissipation member.

2. The heat dissipation structure according to claim 1, further comprising:
a second bus bar made of metal which is provided on an opposite side from the bus bar to interpose the semiconductor circuit breaker.

3. The heat dissipation structure according to claim 2, further comprising:
a control terminal which transmits a control signal to control the switching by the semiconductor circuit breaker to the semiconductor circuit breaker; and
a resin member which seals an entirety of the semiconductor circuit breakers and apart of each of the control terminal, the bus bar, and the second bus bar,
wherein a remainder of the control terminal, a remainder of the second bus bar, and a portion of a remainder of the bus bar, which are not sealed by the resin member, protrude in the same direction from the resin member, and
wherein another portion of the remainder of the bus bar which is not sealed by resin member, contacts the heat pipe.

4. The heat dissipation structure according to claim 1,
wherein when the semiconductor circuit breaker is provided in a vicinity of a battery which is mounted in a vehicle, at least one of a vehicle body of the vehicle and a cover of the battery is used as the heat dissipation member.
